(19) United States
(12) Patent Application Publication
(10) Pub. No.: US 2023/0327622 A1
(43) Pub. Date: Oct. 12, 2023

(54) TRANSIMPEDANCE AMPLIFIER DEVICE AND SENSOR SYSTEM

(71) Applicant: Robert Bosch GmbH, Stuttgart (DE)

(72) Inventors: Robert Wolf, Dresden (DE); Rico Srowik, Radebeul (DE)

(21) Appl. No.: 18/297,584

(22) Filed: Apr. 7, 2023

(30) Foreign Application Priority Data
Apr. 11, 2022 (DE) 10 2022 203 630.1

(51) Int. Cl. H03F 3/45; H03F 1/26

(52) U.S. Cl. CPC H03F 3/45475; H03F 1/26

(57) ABSTRACT

A two-stage transimpedance amplifier device having a transimpedance amplifier and a post-connected voltage differential amplifier. One of the two amplifiers receives a signal from the respective other amplifier as a reference signal. In this way, a noise compensation is able to be achieved.

### FIELD

The present invention relates to a transimpedance amplifier device and to a sensor device having such a transimpedance amplifier device.

### BACKGROUND INFORMATION

Sensors as they are used in numerous application fields for the acquisition of physical variables are able to supply an output signal that corresponds to the acquired physical variable, e.g., in the form of a corresponding current. For example, optical sensors such as photodiodes can supply an output current that corresponds to the acquired light. So-called transimpedance amplifiers, for instance, may be used to convert such an electric current into a voltage which corresponds to the current.

German Patent No. DE 10 31 1096 B4, for instance, describes an electronic circuit for a transimpedance amplifier for converting a current of a current source into a corresponding output voltage.

### SUMMARY

The present invention provides a transimpedance amplifier device and a sensor device. Advantageous example embodiments of the present invention are disclosed herein.

An example embodiment of the present invention provides:

A transimpedance amplifier device, which has a transimpedance amplifier and a voltage differential amplifier. The transimpedance amplifier includes a first input connection, a second input connection, and an output connection. The transimpedance amplifier is designed to supply at the output connection an output signal that corresponds to an input current flowing at the first input connection. The voltage differential amplifier includes a first input connection, a second input connection, and an output connection. The voltage differential amplifier is designed to supply at the output connection an output signal that corresponds to a voltage differential between the first input connection and the second input connection. The first input connection of the transimpedance amplifier is designed to be connected to a signal source. In addition, the output connection of the transimpedance amplifier is electrically connected to the first input connection of the voltage differential amplifier. Either the transimpedance amplifier or the voltage differential amplifier is designed to supply a reference signal at the second input of the respective other amplifier. The reference signal has a noise component which corresponds to a noise component at the first input of the respective amplifier.

Also provided according to an example embodiment of the present invention is:

A sensor system which has a sensor and a transimpedance amplifier device according to the present invention. The sensor is designed to supply an output signal that corresponds to a physical variable. More specifically, the sensor is designed to supply the output signal at the first input connection of the transimpedance amplifier.

The present invention is based on the understanding that in two-stage transimpedance amplifier devices provided with a transimpedance amplifier and a post-connected voltage amplifier, a reference signal must normally be supplied at both amplifier stages. These reference signals usually include noise. The noise components of the two reference signals for the transimpedance amplifier and the post-connected voltage amplifier thus superpose.

Therefore, the present invention takes this understanding into account and provides a transimpedance amplifier device which has better amplification characteristics with regard to the noise components. To this end, it is provided according to an example embodiment of the present invention to advantageously connect the two amplifier components to one another in such a way that the noise component of the output signal is minimized. More specifically, the supply of a reference signal instead of a reference voltage is provided at one of the two amplifier stages, the reference signal originating from the respective other amplifier stage. As a result, this reference signal has a noise component that corresponds to a noise component of the respective other amplifier stage. This makes it possible to minimize the noise component in the entirety of the transimpedance amplifier device.

The input signal supplied at the first input of the transimpedance amplifier of the transimpedance amplifier device may be a current signal, that is, a signal having a variable current intensity. Such a signal, for instance, is able to be supplied by a corresponding sensor which supplies an output current that corresponds to a sensor variable. The transimpedance amplifier device according to the present invention can convert such a current signal into an output voltage that corresponds to a current intensity applied at the input of the transimpedance amplifier device. More specifically, an especially low-noise conversion of the input current into an output voltage is possible with the aid of the transimpedance amplifier device according to the present invention.

According to one example embodiment of the present invention, the reference signal at the second input of the voltage differential amplifier corresponds to an electric voltage at the first input of the transimpedance amplifier. As an alternative, the reference signal at the second input of the transimpedance amplifier may correspond to an internal voltage of the voltage differential amplifier. In other words, a reference signal that corresponds to a voltage in the respective other amplifier is supplied at one of the two amplifiers. Such a signal may then also include the noise components of the reference signal in the one amplifier at the respective other amplifier. Through a suitable interconnection, the noise components in the two amplifiers are able to be processed in opposite manners.

According to one example embodiment of the present invention, the first input connection of the transimpedance amplifier is connected to an inverting input of an internal amplifier of the transimpedance amplifier, and the second input connection of the transimpedance amplifier is connected to a non-inverting input of the internal amplifier. Moreover, the first input connection of the voltage differential amplifier may be an inverting input, and the second input connection of the voltage differential amplifier may be a non-inverting input. The input signal for the transimpedance amplifier device is therefore supplied at the input of the transimpedance amplifier which is connected to the inverting input of the internal amplifier, and the output of the transimpedance amplifier is connected to a non-inverting input of the voltage differential amplifier. Depending on the application case, deviating configurations are of course possible as well.

According to one example embodiment of the present invention, the second input connection of the transimpedance amplifier is electrically connected to a reference voltage source, and the first input connection of the transimpedance amplifier is electrically connected to the second input connection of the voltage differential amplifier.

According to an alternative embodiment of the present invention, the second input connection of the voltage differential amplifier is electrically connected to a reference voltage source. In addition, a reference signal is able to be supplied by the voltage differential amplifier at the second input connection of the transimpedance amplifier. For instance, this reference signal from the voltage differential amplifier may be a signal which is generated on the basis of the input signal at the first input connection of the voltage differential amplifier.

According to one embodiment of the present invention, the transimpedance amplifier and the voltage differential amplifier are implemented as a shared integrated circuit. This makes it possible to realize an especially compact and efficient circuit system.

In one embodiment of the sensor system of the present invention, the sensor is designed to supply an output current at the first input connection of the transimpedance amplifier of the transimpedance amplifier device that corresponds to the physical variable acquired with the aid of a sensor. Accordingly, the transimpedance amplifier device is able to convert this electric current into a corresponding electric voltage and to supply it at the output.

If advantageous, the above embodiments and refinements are freely combinable with one another. Further embodiments, refinements and implementations of the present invention also include combinations of features of the present invention not explicitly mentioned or described in the above or the following text in connection with the exemplary embodiments. In particular, in view of the disclosure herein, one skilled in the art will also add individual aspect as improvements or supplementations to the respective basic forms of the present invention.

### BRIEF DESCRIPTION OF THE DRAWINGS

Further features and advantages of the present invention will be described in the following text based on the figures.

FIG. 1 shows a block diagram of a sensor system having a transimpedance amplifier device according to one example embodiment of the present invention.

FIG. 2 shows a block diagram of a transimpedance amplifier device according to one example embodiment of the present invention.

FIG. 3 shows a schematic circuit diagram of a transimpedance amplifier device according to one example embodiment of the present invention.

FIG. 4 shows a schematic circuit diagram of a transimpedance amplifier device according to a further example embodiment of the present invention.

FIG. 5 shows a block diagram of a transimpedance amplifier device according to one example embodiment of the present invention.

FIG. 6 shows a schematic circuit diagram of a transimpedance amplifier device according to a further example embodiment of the present invention.

Unless stated otherwise, the same reference numerals in the figures relate to the same or functionally equivalent components.

### DETAILED DESCRIPTION OF EXAMPLE EMBODIMENTS

FIG. 1 shows a block diagram of a sensor system according to one embodiment. The sensor system includes a sensor 2 and a transimpedance amplifier device 1. Sensor 2 may be any kind of sensor that supplies an electric current that corresponds to a physical variable. For example, sensor 2 may be a photodiode whose forward current corresponds to a light intensity impinging upon the photodiode. Any other sensors 2 are naturally possible as well.

Transimpedance amplifier device 1 converts the electric current emanating from sensor 2 into a corresponding electric voltage. Transimpedance amplifier device 1 includes a transimpedance amplifier 10 and a differential voltage amplifier 20 for this purpose. The method of functioning of this transimpedance amplifier device 1 will be described in greater detail in the following text.

As mentioned above, transimpedance amplifier device 1 includes a transimpedance amplifier 10 and a post-connected voltage differential amplifier 20. Transimpedance amplifier 10 has a first input connection 11 and a second input connection 12. For example, a sensor 2 is able to supply a current signal such as an electric current at first input connection 11. A reference signal, in particular a reference voltage, can be provided by a reference voltage source 30 at second input connection 12, for instance. Transimpedance amplifier 10 is able to generate an electric voltage that is proportional to the input current at first input connection 11 and output an output signal at output connection 13 that corresponds to the difference between this voltage and the reference voltage applied at second input connection 12.

Transimpedance amplifier device 1 includes a voltage differential amplifier 20, which is connected in series. This voltage differential amplifier 20 has a first input connection 21 and a second input connection 22. One of the two input connections 21, 22 may be an inverting input, and the respective other input 21, 22 may be a non-inverting input. Voltage differential amplifier 20 thus is able to supply at its output connection 23 an output voltage which corresponds to the voltage differential between first input connection 21 and second input connection 22.

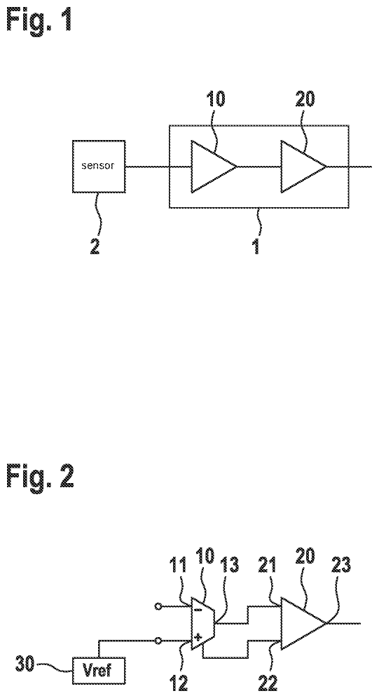

As shown in FIG. 2, first input connection 21, for example, is able to be connected to output connection 13 of transimpedance amplifier 10. A reference signal may be supplied at second input connection 22. This reference signal can come from transimpedance amplifier 10, for example. More specifically, this reference signal may be a signal that has a noise component which corresponds to a noise component of the output signal of transimpedance amplifier 10. Since the noise component of the output signal of transimpedance amplifier 10 corresponds to the noise components at the input due to the internal amplification in transimpedance amplifier 10, the noise component at the output is also a function of the noise component of the reference voltage at second input connection 11 of transimpedance amplifier 10. By supplying a reference signal from transimpedance amplifier 10 as a reference signal for the post-connected voltage differential amplifier 20, the post-connected voltage differential amplifier 20 is able to compensate for the noise components attributable to transimpedance amplifier 10.

The voltage signal output by voltage differential amplifier 20 at output connection 23 is able to be output as an output signal of transimpedance amplifier device 1.

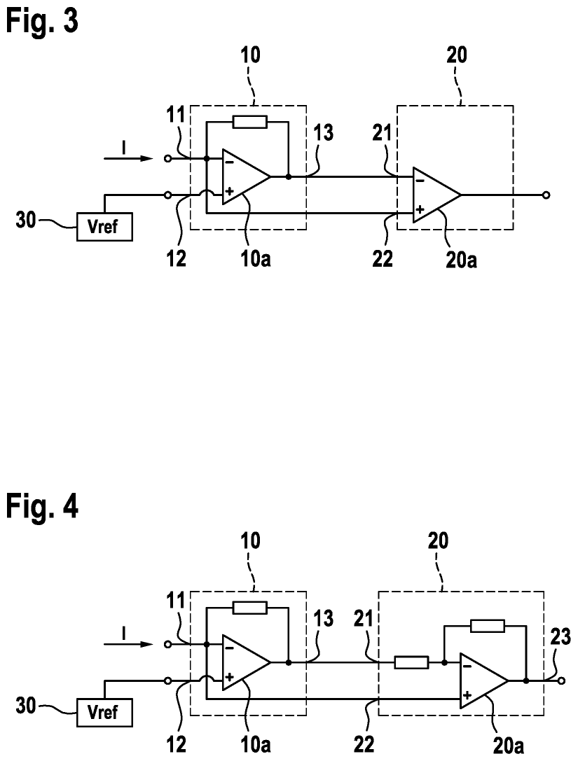

FIG. 3 shows a schematic representation of a circuit diagram for a circuit array of a transimpedance amplifier device 1 according to one embodiment.

As may be gathered from FIG. 3, the reference signal supplied at second input connection 22 of voltage differential amplifier 20 is a voltage which is applied at the inverting connection of internal amplifier 10a of transimpedance amplifier 10. The above-mentioned reference voltage is applied at second input connection 12 of transimpedance amplifier 10. Since a signal from transimpedance amplifier 10 is thereby applied both at inverting input 21 and at non-inverting input 22 of voltage differential amplifier 20, transimpedance amplifier 10 is able to compensate for the noise components.

FIG. 4 shows a schematic representation of a circuit diagram of a transimpedance amplifier device 1 according to an alternative embodiment. This embodiment differs from the above-described embodiment according to FIG. 3 in particular in that output 13 of transimpedance amplifier 10 is connected via a resistor of voltage differential amplifier 20 at first input connection 22 to the inverting input of an internal differential amplifier 20a of voltage differential amplifier 20. In addition, non-inverting input 22 of voltage differential amplifier 20 is electrically connected to inverting input 11 of transimpedance amplifier 10.

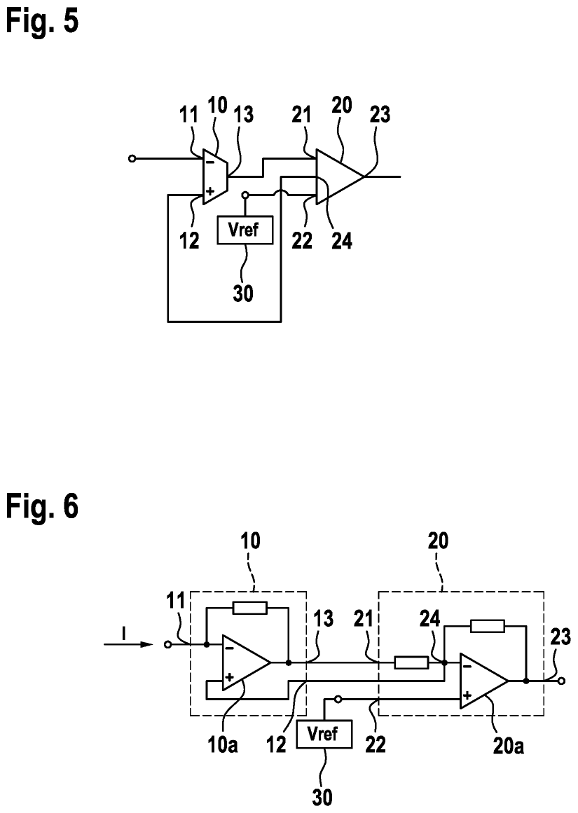

FIG. 5 shows a schematic representation of a circuit diagram of a transimpedance amplifier device 1 according to an alternative embodiment. The embodiment shown in FIG. 5 differs from the above-described embodiments especially in that in this case, the reference voltage is supplied by reference voltage source 30 at second input connection 22 of voltage differential amplifier 20. In addition, at second input connection 12 of transimpedance amplifier 10, a connection 24 of voltage differential amplifier 20 supplies a reference signal which includes noise components of the input signals of voltage differential amplifier 20. An exemplary embodiment for the supply of such a reference signal will be described in greater detail in the following text.

FIG. 6 shows a schematic representation of a circuit diagram of a transimpedance amplifier device 1 according to the embodiment described above in connection with FIG. 5. As can be seen, the input signal is supplied via first input connection 11 of transimpedance amplifier 10 at an inverting connection of internal differential amplifier 20a. The second, non-inverting connection of internal differential amplifier 20a is connected to an internal node 24 of the inverting connection of differential amplifier 20a in voltage differential amplifier 20. This node 24, for example, is connected via a resistor to first input connection 22 of voltage differential amplifier 20. Second input connection 22 of voltage differential amplifier 20 is connected to reference voltage source 30. Supplied as a reference voltage at transimpedance amplifier 10 thus is a signal from internal node 24 of voltage differential amplifier 20 which includes noise components that correspond to the noise components at the input of differential amplifier 20. Because of the difference calculation by internal differential amplifier 10a in transimpedance amplifier 10, it is therefore possible to minimize or possibly eliminate the occurring noise components.

All above-described embodiments are based on the basic principle of the present invention according to which a reference signal, which has noise components that correspond to the noise components of the respective other input connection, is supplied as a reference signal of one of the two amplifiers, either to transimpedance amplifier 10 or voltage differential amplifier 20, at one of input connections 12, 22. This allows for a compensation of noise components within transimpedance amplifier device 1.

For example, such a transimpedance amplifier device may be realized as an integrated circuit. More specifically, both the transimpedance amplifier and the voltage differential amplifier may be implemented on a shared integrated circuit.

In summary, the present invention relates to a two-stage transimpedance amplifier device having a transimpedance amplifier and a post-connected voltage differential amplifier.

To one of the two amplifiers, a signal is supplied as a reference signal by the respective other amplifier. This makes it possible to achieve a noise compensation.

1-10. (canceled)

11. A transimpedance amplifier device, comprising:
a transimpedance amplifier having a first input connection, a second input connection, and an output connection, the transimpedance amplifier being configured to supply at the output connection of the transimpedance amplifier an output signal that corresponds to a current at the first input connection; and
a voltage differential amplifier having a first input connection, a second input connection, and an output connection, the voltage differential amplifier being configured to supply at the output connection of the voltage differential amplifier an output signal that corresponds to a voltage differential between the first input connection of the voltage differential amplifier and the second input connection of the voltage differential amplifier;
wherein the first input connection of the transimpedance amplifier being configured to be connected to a signal source, and the output connection of the transimpedance amplifier being electrically connected to the first input connection of the voltage differential amplifier, and
the transimpedance amplifier or the voltage differential amplifier being configured to supply a reference signal at the second input of a respective other of the transimpedance amplifier or the differential amplifier, and the reference signal has a noise component that corresponds to a noise component at the first input connection of the respective other of the transimpedance amplifier or the differential amplifier.

12. The transimpedance amplifier device as recited in claim 11, wherein the reference signal at the second input of the voltage differential amplifier corresponds to a voltage at the first input of the transimpedance amplifier.

13. The transimpedance amplifier device as recited in claim 11, wherein the reference signal is supplied by the transimpedance amplifier at the second input connection of the voltage differential amplifier, and the second input connection of the transimpedance amplifier is electrically connected to a reference voltage source.

14. The transimpedance amplifier device as recited in claim 11, wherein:
the first input connection of the transimpedance amplifier is connected to an inverting input of an internal differential amplifier, and the second input connection of the transimpedance amplifier is connected to a non-inverting input of the internal differential amplifier, and
the first input connection of the voltage differential amplifier is connected to an inverting input of an internal differential amplifier of the voltage differential amplifier, and the second input connection of the voltage differential amplifier is connected to a non-inverting input of the internal differential amplifier.

15. The transimpedance amplifier device as recited in claim 11, wherein:
the first input connection of the transimpedance amplifier is connected to an inverting input of an internal differential amplifier, and the second input connection of the transimpedance amplifier is connected to a non-inverting input of the internal differential amplifier, and
the first input connection of the voltage differential amplifier is connected to a non-inverting input of an internal differential amplifier of the voltage differential amplifier, and the second input connection of the voltage differential amplifier is connected to an inverting input of the internal differential amplifier.

16. The transimpedance amplifier device as recited in claim 14, wherein:
the second input connection of the transimpedance amplifier is electrically connected to a reference voltage source, and
the first input connection of the transimpedance amplifier is electrically connected to the second input connection of the voltage differential amplifier.

17. The transimpedance amplifier device as recited in claim 14, wherein:
the second input connection of the voltage differential amplifier is electrically connected to a reference voltage source, and
the second input connection of the transimpedance amplifier is electrically connected to the first inverting connection of the internal differential amplifier of the voltage differential amplifier.

18. The transimpedance amplifier device as recited in claim 11, wherein the transimpedance amplifier and the voltage differential amplifier are implemented as a shared integrated circuit.

19. A sensor system, comprising:
a sensor configured to supply an output signal that corresponds to a physical variable; and
a transimpedance amplifier device including:
a transimpedance amplifier having a first input connection, a second input connection, and an output connection, the transimpedance amplifier being configured to supply at the output connection of the transimpedance amplifier an output signal that corresponds to a current at the first input connection, and
a voltage differential amplifier having a first input connection, a second input connection, and an output connection, the voltage differential amplifier being configured to supply at the output connection of the voltage differential amplifier an output signal that corresponds to a voltage differential between the first input connection of the voltage differential amplifier and the second input connection of the voltage differential amplifier,
wherein the first input connection of the transimpedance amplifier being configured to be connected to a signal source, and the output connection of the transimpedance amplifier being electrically connected to the first input connection of the voltage differential amplifier, and
the transimpedance amplifier or the voltage differential amplifier being configured to supply a reference signal at the second input of a respective other of the transimpedance amplifier or the differential amplifier, and the reference signal has a noise component that corresponds to a noise component at the first input connection of the respective other of the transimpedance amplifier or the differential amplifier;
wherein the sensor is configured to supply the output signal at the first input connection of the transimpedance amplifier.

20. The sensor system as recited in claim 19, wherein the sensor is configured to supply an output current that corresponds to a physical variable at the transimpedance amplifier device.
